(19) United States
(12) Patent Application Publication
(10) Pub. No.: US 2025/0192029 A1
(43) Pub. Date: Jun. 12, 2025

(54) SEMICONDUCTOR DEVICE

(71) Applicant: Samsung Electronics Co., Ltd., Suwon-si (KR)

(72) Inventors: Wonkeun Chung, Suwon-si (KR); Hyunwoo Kang, Suwon-si (KR); Geunwoo Kim, Suwon-si (KR); Mingyu Kim, Suwon-si (KR); Wandon Kim, Suwon-si (KR); Hyoseok Choi, Suwon-si (KR)

(21) Appl. No.: 18/766,960

(22) Filed: Jul. 9, 2024

(30) Foreign Application Priority Data
Dec. 12, 2023 (KR) 10-2023-0179965

(51) Int. Cl. H01L 23/522; H01L 23/528; H01L 23/532; H01L 23/544

(52) U.S. Cl. CPC H01L 23/5226; H01L 23/5228; H01L 23/5283; H01L 23/53261; H01L 23/544; H01L 2223/54426

(57) ABSTRACT

A semiconductor device includes lower conductive patterns on a substrate and horizontally spaced apart from each other, upper conductive patterns on the lower conductive patterns and horizontally spaced apart from each other, and a first via contact and a second via contact between the lower and upper conductive patterns and horizontally spaced apart from each other. The first via contact has a first width in a direction parallel to a top surface of the substrate. The second via contact has a second width in the direction that is wider than the first width. The second via contact includes a first metal pattern and a second metal pattern on the first metal pattern. The first metal pattern includes a same material as the first via contact, and the second metal pattern includes a different material from the first metal pattern and the first via contact.

### CROSS-REFERENCE TO RELATED APPLICATIONS

This U.S. non-provisional patent application claims priority under 35 U.S.C. § 119 to Korean Patent Application No. 10-2023-0179965, filed on Dec. 12, 2023, in the Korean Intellectual Property Office, the entire contents of which are hereby incorporated by reference.

### BACKGROUND OF THE INVENTION

The present disclosure relates to a semiconductor device, and in particular, to a semiconductor device including field effect transistors.

A semiconductor device may include an integrated circuit composed of metal-oxide-semiconductor field-effect transistors (MOSFETs). To meet an increasing demand for a semiconductor device with a small pattern size and a reduced design rule, the MOSFETs are being aggressively scaled down. The scale-down of the MOSFETs may lead to deterioration in operational properties of the semiconductor device. A variety of studies are being conducted to overcome technical limitations associated with the scale-down of the semiconductor device and to provide a high performance semiconductor device.

### SUMMARY OF THE INVENTION

Some embodiments of the inventive concepts provide a semiconductor device including a via contact with a reduced resistance and a method of fabricating the same.

Some embodiments of the inventive concepts provide a semiconductor device including a via contact and an overlay key, which can be formed at the same time, and a method of fabricating the same.

According to some embodiments of the inventive concepts, a semiconductor device may include lower conductive patterns on a substrate and horizontally spaced apart from each other, upper conductive patterns on the lower conductive patterns and horizontally spaced apart from each other, and a first via contact and a second via contact between the lower conductive patterns and the upper conductive patterns and horizontally spaced apart from each other. The first via contact may have a first width in a first direction parallel to a top surface of the substrate, and the second via contact may have a second width in the first direction that is wider than the first width. The second via contact may include a first metal pattern and a second metal pattern on the first metal pattern. The first metal pattern may include a same material as the first via contact, and the second metal pattern may include a different material from the first metal pattern and the first via contact.

According to some embodiments of the inventive concepts, a semiconductor device may include transistors on a substrate, lower conductive patterns electrically connected to gate terminals or source/drain terminals of the transistors and horizontally spaced apart from each other, upper conductive patterns on the lower conductive patterns and horizontally spaced apart from each other, and a first via contact and a second via contact between the lower conductive patterns and the upper conductive patterns and horizontally spaced apart from each other. The first via contact may electrically connect a first lower conductive pattern among the lower conductive patterns to a first upper conductive pattern among the upper conductive patterns, and the second via contact may electrically connect a second lower conductive pattern among the lower conductive patterns to a second upper conductive pattern among the upper conductive patterns. The first via contact may have a first width in a first direction parallel to a top surface of the substrate, and the second via contact may have a second width in the first direction that is wider than the first width. The second via contact may include a first metal pattern and a second metal pattern on the first metal pattern. The first metal pattern may include a same material as the first via contact, and the second metal pattern may include a different material from the first metal pattern and the first via contact.

According to some embodiments of the inventive concepts, a semiconductor device may include a first lower conductive pattern on a substrate, a second lower conductive pattern on the substrate and horizontally spaced apart from the first lower conductive pattern, a first upper conductive pattern on the first lower conductive pattern, a second upper conductive pattern on the second lower conductive pattern and horizontally spaced apart from the first upper conductive pattern, a first via contact electrically connected between the first lower conductive pattern and the first upper conductive pattern, and a second via contact electrically connected between the second lower conductive pattern and the second upper conductive pattern. The first via contact may have a first width in a direction parallel to a top surface of the substrate, and the second via contact may have a second width in the direction that is different from the first width. The second via contact may include a first metal pattern and a second metal pattern on the first metal pattern. One of the first and second metal patterns may include a same material as the first via contact, and another one of the first and second metal patterns may include a different material from the first via contact.

### BRIEF DESCRIPTION OF THE DRAWINGS

FIG. 1 is a sectional view illustrating a semiconductor device according to some embodiments of the inventive concepts.

FIGS. 2 to 5 are sectional views illustrating a method of fabricating a semiconductor device according to some embodiments of the inventive concepts.

FIGS. 6 to 9 are sectional views illustrating a semiconductor device according to some embodiments of the inventive concepts.

FIG. 10 is a sectional view illustrating a semiconductor device according to some embodiments of the inventive concepts.

FIGS. 11 to 13 are sectional views illustrating a method of fabricating a semiconductor device, according to some embodiments of the inventive concepts.

FIGS. 14 and 15 are sectional views illustrating a semiconductor device according to some embodiments of the inventive concepts.

FIG. 16 is a sectional view illustrating a semiconductor device according to some embodiments of the inventive concepts.

### DETAILED DESCRIPTION

Example embodiments of the inventive concepts will now be described more fully with reference to the accompanying drawings, in which example embodiments are shown.

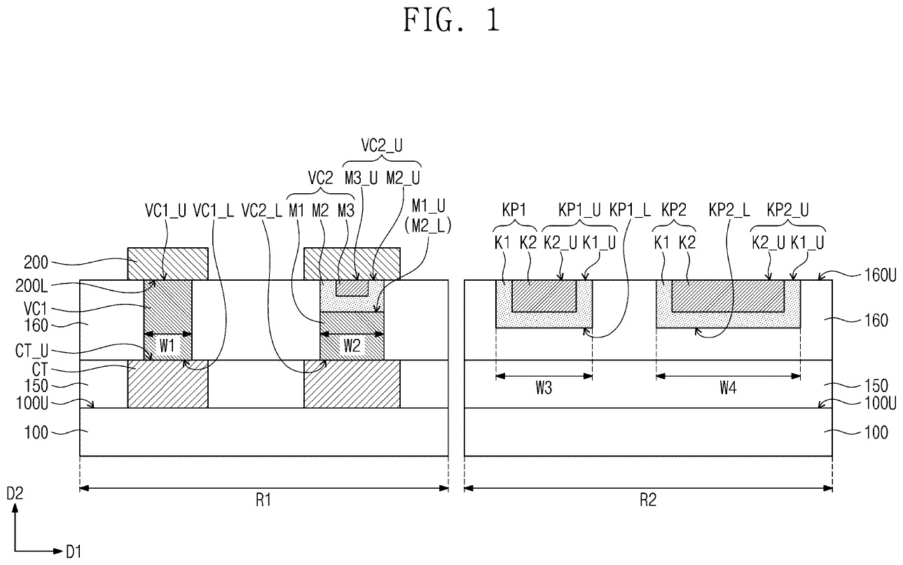

FIG. 1 is a sectional view illustrating a semiconductor device according to some embodiments of the inventive concepts.

Referring to FIG. 1, a substrate 100 including at least two different regions (e.g., a first region R1 and a second region R2) may be provided. The substrate 100 may be a semiconductor substrate. For example, the substrate 100 may be a silicon substrate, a germanium substrate, a silicon-germanium substrate, or a silicon-on-insulator (SOI) substrate.

Lower conductive patterns CT may be disposed on the first region R1 of the substrate 100 and may be horizontally spaced apart from each other. In some embodiments, the lower conductive patterns CT may be spaced apart from each other in a first direction D1 that is parallel to a top surface 100U of the substrate 100. The lower conductive patterns CT may include a conductive material (e.g., a metallic material).

A first interlayer insulating layer 150 may be disposed on the first region R1 of the substrate 100 and may be on (e.g., may cover) the lower conductive patterns CT. Top surfaces CT_U of the lower conductive patterns CT may not have the first interlayer insulating layer 150 thereon (e.g., may not be covered by the first interlayer insulating layer 150) and may be exposed to the outside of the first interlayer insulating layer 150. The first interlayer insulating layer 150 may extend to the second region R2 of the substrate 100 to be on (e.g., to cover) the top surface 100U of the substrate 100. The first interlayer insulating layer 150 may include at least one of a silicon oxide layer, a silicon nitride layer, a silicon oxynitride layer, or low-k dielectric layers.

A second interlayer insulating layer 160 may be disposed on the first interlayer insulating layer 150 to be on (e.g., to cover) the top surfaces CT_U of the lower conductive patterns CT. The second interlayer insulating layer 160 may be disposed on the first interlayer insulating layer 150 on the first region R1 and may extend to be on (e.g., to cover) the first interlayer insulating layer 150 on the second region R2. The second interlayer insulating layer 160 may include at least one of a silicon oxide layer, a silicon nitride layer, a silicon oxynitride layer, or low-k dielectric layers.

A first via contact VC1 and a second via contact VC2 may be disposed on the lower conductive patterns CT and in the second interlayer insulating layer 160 on the first region R1. The first and second via contacts VC1 and VC2 may be spaced apart from each other in a horizontal direction (e.g., the first direction D1). Each of the first and second via contacts VC1 and VC2 may be provided to penetrate (i.e., extend into) the second interlayer insulating layer 160 and may be electrically connected to a corresponding one of the lower conductive patterns CT.

The first via contact VC1 may have a first width W1 in a direction (e.g., the first direction D1) parallel to the top surface 100U of the substrate 100, and the second via contact VC2 may have a second width W2 in the direction (e.g., the first direction D1) parallel to the top surface 100U of the substrate 100. The second width W2 may be larger (i.e., wider) than the first width W1.

The first via contact VC1 may include a metallic material, and in some embodiments, it may include a metallic material or a metal alloy containing at least one of tungsten (W), molybdenum (Mo), ruthenium (Ru), iridium (Ir), or copper (Cu). For example, the first via contact VC1 may be formed of or include molybdenum (Mo).

The second via contact VC2 may include a first metal pattern M1 and a second metal pattern M2 on the first metal pattern M1. The first metal pattern M1 and the second metal pattern M2 may include different materials from each other. The first metal pattern M1 may include a metallic material or a metal alloy containing at least one of tungsten (W), molybdenum (Mo), ruthenium (Ru), iridium (Ir), or copper (Cu). The second metal pattern M2 may include a metallic material, a metal alloy, a metal oxide material, a metal nitride material, or a metal oxynitride material containing at least one of tungsten (W), molybdenum (Mo), ruthenium (Ru), cobalt (Co), iridium (Ir), titanium (Ti), or tantalum (Ta). The first metal pattern M1 may include the same material as the first via contact VC1, and the second metal pattern M2 may include a material that is different from the first metal pattern M1 and the first via contact VC1. In some embodiments, the first metal pattern M1 may be formed of or include molybdenum (Mo), and the second metal pattern M2 may be formed of or include tungsten (W).

In some embodiments, the second via contact VC2 may further include a third metal pattern M3 on the second metal pattern M2. The third metal pattern M3 may include a metallic material, a metal alloy material, a metal oxide material, a metal nitride material, or a metal oxynitride material containing at least one of tungsten (W), molybdenum (Mo), ruthenium (Ru), iridium (Ir), copper (Cu), cobalt (Co), titanium (Ti), or tantalum (Ta). The third metal pattern M3 may be formed of or include the same material as the first metal pattern M1 or the second metal pattern M2. As an example, the third metal pattern M3 may be formed of or include molybdenum (Mo) or tungsten (W).

The first metal pattern M1 may be interposed between a corresponding one of the lower conductive patterns CT and the second metal pattern M2. In some embodiments, the uppermost surface M1_U of the first metal pattern M1 may be located at a height lower than the uppermost surface VC1_U of the first via contact VC1. In the present specification, the term “height” may refer to a distance that is measured from the top surface 100U of the substrate 100 in a second direction D2, which is perpendicular to the top surface 100U of the substrate 100. In other words, a height may be taken in the second direction D2, with the top surface 100U of the substrate 100 providing a base reference plane. The second metal pattern M2 may be interposed between the first metal pattern M1 and the third metal pattern M3. The second metal pattern M2 may extend onto side surfaces of the third metal pattern M3 along the second direction D2. In other words, a first portion of the second metal pattern M2 may be between the first metal pattern M1 and the third metal pattern M3, and second and third portions of the second metal pattern M2 may be on side surfaces of the third metal pattern M3, respectively. The second metal pattern M2 may extend into a region between the side surfaces of the third metal pattern M3 and the second interlayer insulating layer 160, along the second direction D2. The second metal pattern M2 may have a ‘U’-shape in a sectional view.

The uppermost surface VC1_U of the first via contact VC1 and the uppermost surface VC2_U of the second via contact VC2 may not have the second interlayer insulating layer 160 thereon (e.g., may not be covered by the second interlayer insulating layer 160) and may be exposed to the outside of the second interlayer insulating layer 160. The uppermost surface VC2_U of the second via contact VC2 may include the uppermost surface M2_U of the second metal pattern M2 and the uppermost surface M3_U of the third metal pattern M3. The uppermost surface VC1_U of the first via contact VC1, the uppermost surface VC2_U of the second via contact VC2, and a top surface 160U of the second interlayer insulating layer 160 may be located at the same height and may be coplanar with each other.

The lowermost surfaces VC1_L and VC2_L of the first and second via contacts VC1 and VC2 may be in contact with the top surfaces CT_U of the lower conductive patterns CT. The lowermost surface VC1_L of the first via contact VC1 may be in contact with the top surface CT_U of a corresponding one of the lower conductive patterns CT, and the lowermost surface VC2_L of the second via contact VC2 may be in contact with the top surface CT_U of a corresponding one of the lower conductive patterns CT. The lowermost surface VC2_L of the second via contact VC2 may correspond to the lowermost surface of the first metal pattern M1.

Upper conductive patterns 200 may be disposed on the second interlayer insulating layer 160 in the first region R1. The upper conductive patterns 200 may be disposed on the lower conductive patterns CT, and the first and second via contacts VC1 and VC2 and the second interlayer insulating layer 160 may be disposed between the lower conductive patterns CT and the upper conductive patterns 200. Each of the first and second via contacts VC1 and VC2 may be provided to penetrate the second interlayer insulating layer 160 and may be connected to a corresponding one of the lower conductive patterns CT and a corresponding one of the upper conductive patterns 200. As used herein, “an element A connected to an element B” (or similar language) means that the element A is physically and/or electrically connected to the element B.

The uppermost surfaces VC1_U and VC2_U of the first and second via contacts VC1 and VC2 may be in contact with bottom surfaces 200L of the upper conductive patterns 200. The uppermost surface VC1_U of the first via contact VC1 may be in contact with the bottom surface 200L of a corresponding one of the upper conductive patterns 200. The uppermost surface VC2_U of the second via contact VC2 may be in contact with the bottom surface 200L of a corresponding one of the upper conductive patterns 200, and the uppermost surface M2_U of the second metal pattern M2 and the uppermost surface M3_U of the third metal pattern M3 may be in contact with the bottom surface 200L of the corresponding upper conductive pattern 200.

A first overlay key pattern KP1 and a second overlay key pattern KP2 may be disposed in the second interlayer insulating layer 160 on the second region R2. The first and second overlay key patterns KP1 and KP2 may be horizontally spaced apart from the first and second via contacts VC1 and VC2 (e.g., in the first direction D1). The first and second overlay key patterns KP1 and KP2 may be spaced apart from each other in a horizontal direction (e.g., the first direction D1). Each of the first and second overlay key patterns KP1 and KP2 may be provided to penetrate a portion of the second interlayer insulating layer 160.

The first overlay key pattern KP1 may have a third width W3 in a direction (e.g., the first direction D1) parallel to the top surface 100U of the substrate 100, and the second overlay key pattern KP2 may have a fourth width W4 in the direction (e.g., the first direction D1) parallel to the top surface 100U of the substrate 100. The fourth width W4 may be larger than the third width W3.

Each of the first and second overlay key patterns KP1 and KP2 may include a first key pattern K1 and a second key pattern K2 on the first key pattern K1. The first key pattern K1 may be interposed between a bottom surface of the second key pattern K2 and the second interlayer insulating layer 160 and may extend in the second direction D2 onto (e.g., to cover) side surfaces of the second key pattern K2. The first key pattern K1 may extend in the second direction D2 and may include portions, which are placed between the side surfaces of the second key pattern K2 and the second interlayer insulating layer 160. The first key pattern K1 may have a ‘U’-shape in a sectional view.

The first key pattern K1 may include a material, which is different from the first via contact VC1 and the first metal pattern M1 of the second via contact VC2. The first key pattern K1 may be formed of or include the same material as the second metal pattern M2 of the second via contact VC2. The second key pattern K2 may be formed of or include the same material as the third metal pattern M3 of the second via contact VC2. As an example, the first key pattern K1 may be formed of or include tungsten (W), and the second key pattern K2 may be formed of or include molybdenum (Mo) or tungsten (W).

The uppermost surface KP1_U of the first overlay key pattern KP1 and the uppermost surface KP2_U of the second overlay key pattern KP2 may not have the second interlayer insulating layer 160 thereon (e.g., may not be covered by the second interlayer insulating layer 160) and may be exposed to the outside of the second interlayer insulating layer 160. Each of the uppermost surface KP1_U of the first overlay key pattern KP1 and the uppermost surface KP2_U of the second overlay key pattern KP2 may include (or be defined by) the uppermost surface K1_U of the first key pattern K1 and the uppermost surface K2_U of the second key pattern K2. The uppermost surface KP1_U of the first overlay key pattern KP1, the uppermost surface KP2_U of the second overlay key pattern KP2, and the top surface 160U of the second interlayer insulating layer 160 may be located at the same height and may be coplanar with each other.

In some embodiments, the lowermost surface KP1_L of the first overlay key pattern KP1 and the lowermost surface KP2_L of the second overlay key pattern KP2 may be located at a height higher than the lowermost surfaces VC1_L and VC2_L of the first and second via contacts VC1 and VC2. The lowermost surface KP1_L of the first overlay key pattern KP1 may correspond to the lowermost surface of the first key pattern K1 of the first overlay key pattern KP1, and the lowermost surface KP2_L of the second overlay key pattern KP2 may correspond to the lowermost surface of the first key pattern K1 of the second overlay key pattern KP2.

In some embodiments, the second width W2 of the second via contact VC2 may be smaller than the third width W3 of the first overlay key pattern KP1 and the fourth width W4 of the second overlay key pattern KP2. In this case, the lowermost surface M2_L of the second metal pattern M2 of the second via contact VC2 may be located at a height higher than the lowermost surfaces KP1_L and KP2_L of the first and second overlay key patterns KP1 and KP2.

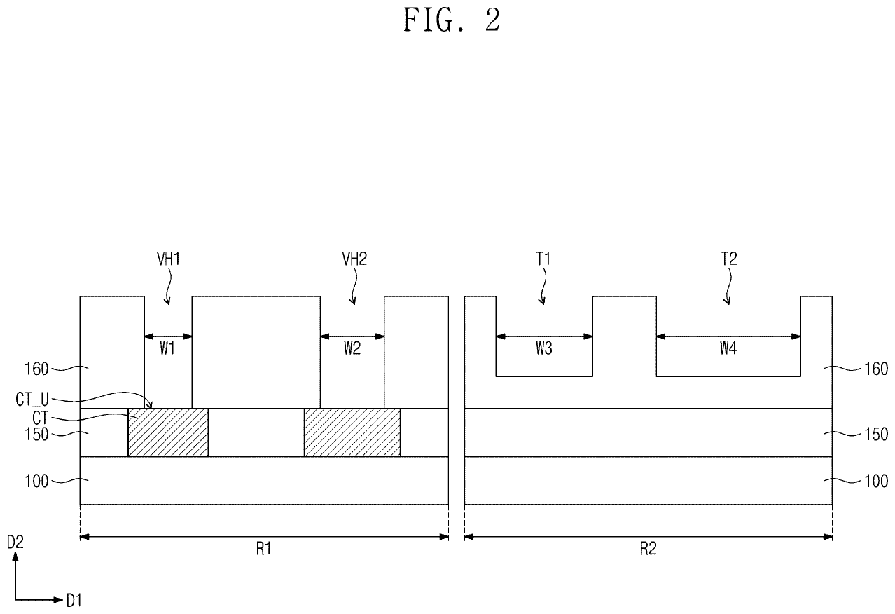

FIGS. 2 to 5 are sectional views illustrating a method of fabricating a semiconductor device according to some embodiments of the inventive concepts. For concise description, an element previously described with reference to FIG. 1 may be identified by the same reference number without repeating an overlapping description thereof.

Referring to FIG. 2, a substrate 100 including at least two different regions (e.g., a first region R1 and a second region R2) may be provided. A first interlayer insulating layer 150 may be formed on (e.g., may cover) the first and second regions R1 and R2 of the substrate 100. Lower conductive patterns CT may be formed on the first region R1 of the substrate 100 and in the first interlayer insulating layer 150. In some embodiments, the formation of the lower conductive patterns CT may include forming lower holes to penetrate the first interlayer insulating layer 150, forming a lower conductive layer on the first interlayer insulating layer 150 to fill the lower holes, and planarizing the lower conductive layer to expose a top surface of the first interlayer insulating layer 150.

A second interlayer insulating layer 160 may be formed on the first interlayer insulating layer 150 to be on (e.g., to cover) the top surfaces CT_U of the lower conductive patterns CT. The second interlayer insulating layer 160 may be formed on (e.g., may cover) the first interlayer insulating layer 150 on the first and second regions R1 and R2.

A first via hole VH1 and a second via hole VH2 may be formed in the second interlayer insulating layer 160 on the first region R1. Each of the first and second via holes VH1 and VH2 may penetrate the second interlayer insulating layer 160 and may expose the top surface CT_U of a corresponding one of the lower conductive patterns CT. In some embodiments, the formation of the first and second via holes VH1 and VH2 may include forming a via mask pattern on the second interlayer insulating layer 160 to have openings defining planar shapes of the first and second via holes VH1 and VH2 and etching the second interlayer insulating layer 160 using the via mask pattern as an etch mask. The first via hole VH1 may have a first width W1 in a direction (e.g., the first direction D1) parallel to the top surface 100U of the substrate 100, and the second via hole VH2 may have a second width W2 in the direction (e.g., the first direction D1) parallel to the top surface 100U of the substrate 100. The second width W2 may be larger than the first width W1.

A first trench T1 and a second trench T2 may be formed in the second interlayer insulating layer 160 on the second region R2. Each of the first and second trenches T1 and T2 may penetrate an upper portion of the second interlayer insulating layer 160 and may expose an inner surface of the second interlayer insulating layer 160. In some embodiments, the formation of the first and second trenches T1 and T2 may include forming a key mask pattern on the second interlayer insulating layer 160 to have openings defining planar shapes of the first and second trenches T1 and T2 and etching the second interlayer insulating layer 160 using the key mask pattern as an etch mask. The first trench T1 may have a third width W3 in a direction (e.g., the first direction D1) parallel to the top surface 100U of the substrate 100, and the second trench T2 may have a fourth width W4 in the direction (e.g., the first direction D1) parallel to the top surface 100U of the substrate 100. The fourth width W4 may be larger than the third width W3.

In some embodiments, the etching process, which is performed to form the first and second via holes VH1 and VH2, and the etching process, which is performed to form the first and second trenches T1 and T2, may be performed at the same time.

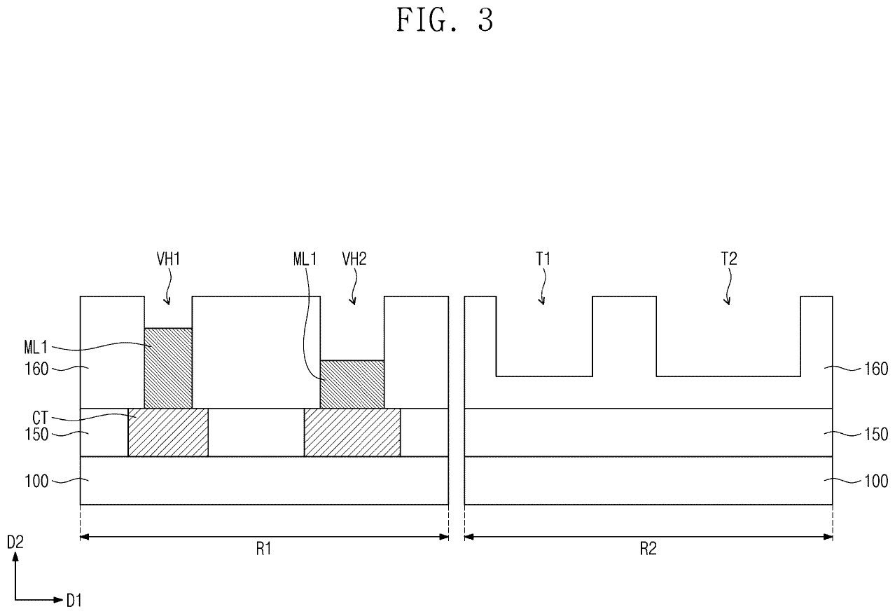

Referring to FIG. 3, a first metal layer ML1 may be formed to partially fill each of the first and second via holes VH1 and VH2. The first metal layer ML1 may include a metallic material with a relatively low resistance and may be formed of or include at least one of metallic materials (tungsten (W), molybdenum (Mo), ruthenium (Ru), iridium (Ir), and copper (Cu)) or alloys thereof.

In some embodiments, the first metal layer ML1 may be formed by a selective growth process using the top surfaces CT_U of the lower conductive patterns CT, which are exposed by the first and second via holes VH1 and VH2, as a seed layer. Thus, the first metal layer ML1 may be grown from the top surfaces CT_U of the lower conductive patterns CT in the second direction D2. Since the second width W2 of the second via hole VH2 is larger than the first width W1 of the first via hole VH1, the uppermost surface of the first metal layer ML1 in the second via hole VH2 may be placed at a height lower than the uppermost surface of the first metal layer ML1 in the first via hole VH1. Since the first metal layer ML1 is formed by the selective growth process using the top surfaces CT_U of the lower conductive patterns CT as a seed layer, the first metal layer ML1 may not be formed in the first and second trenches T1 and T2 exposing an inner surface of the second interlayer insulating layer 160.

The first metal layer ML1 may be formed using at least one of, for example, atomic layer deposition (ALD), chemical vapor deposition (CVD), or electroplating processes.

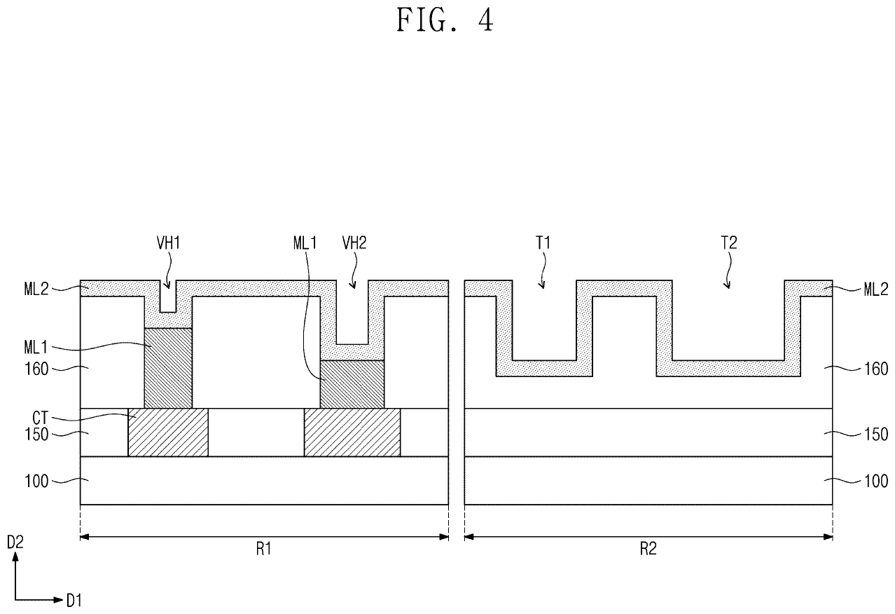

Referring to FIG. 4, a second metal layer ML2 may be formed on the second interlayer insulating layer 160 to partially fill each of the first and second via holes VH1 and VH2 and each of the first and second trenches T1 and T2. The second metal layer ML2 may include a material different from the first metal layer ML1. The second metal layer ML2 may include a metallic material, a metal alloy, a metal oxide material, a metal nitride material, or a metal oxynitride material containing at least one of tungsten (W), molybdenum (Mo), ruthenium (Ru), cobalt (Co), iridium (Ir), titanium (Ti), or tantalum (Ta).

The second metal layer ML2 may be formed by a conformal growth process to conformally cover an inner surface of each of the first and second via holes VH1 and VH2, a top surface of the second interlayer insulating layer 160, and an inner surface of each of the first and second trenches T1 and T2. The second metal layer ML2 may be formed using at least one of, for example, atomic layer deposition (ALD), chemical vapor deposition (CVD), physical vapor deposition (PVD), or electroplating processes.

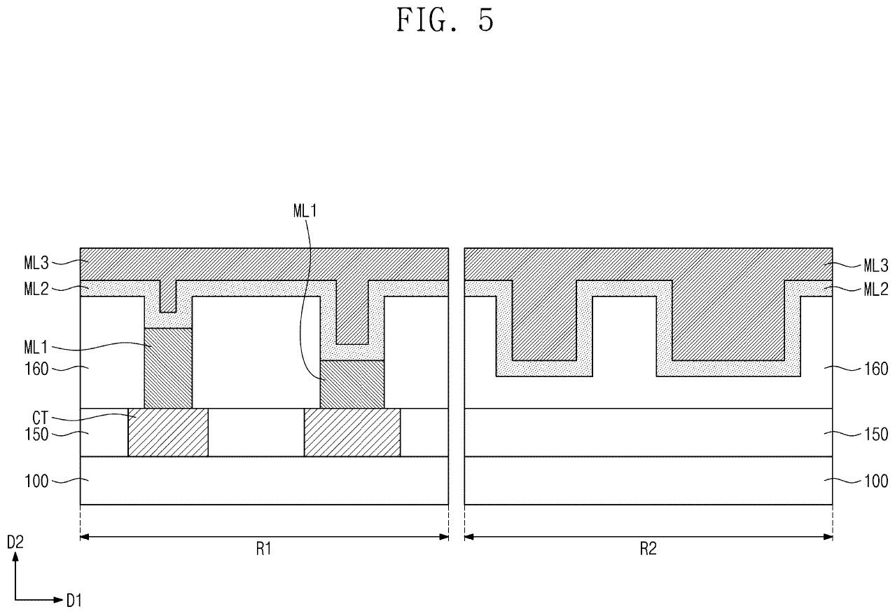

Referring to FIG. 5, a third metal layer ML3 may be formed on the second metal layer ML2 to fill a remaining portion of each of the first and second via holes VH1 and VH2 and a remaining portion of each of the first and second trenches T1 and T2. The third metal layer ML3 may be formed by a conformal growth process and may be formed to have a thickness that is thick enough to fully fill the remaining portion of each of the first and second via holes VH1 and VH2 and the remaining portion of each of the first and second trenches T1 and T2. In some embodiments, the third metal layer ML3 may be formed using at least one of atomic layer deposition (ALD), chemical vapor deposition (CVD), physical vapor deposition (PVD), or electroplating processes. The third metal layer ML3 may include the same material as the first metal layer ML1 or the second metal layer ML2. The third metal layer ML3 may include a metallic material, a metal alloy material, a metal oxide material, a metal nitride material, or a metal oxynitride material containing at least one of tungsten (W), molybdenum (Mo), ruthenium (Ru), iridium (Ir), copper (Cu), cobalt (Co), titanium (Ti), or tantalum (Ta).

Referring back to FIG. 1, a planarization process may be performed on the third metal layer ML3. The planarization process may be performed to expose the first metal layer ML1 in the first via hole VH1. As a result of the planarization process, the third metal layer ML3 and the second metal layer ML2 on the second interlayer insulating layer 160 may be removed, and an upper portion of the second interlayer insulating layer 160 may be removed. A first via contact VC1, a second via contact VC2, a first overlay key pattern KP1, and a second overlay key pattern KP2 may be formed in the second interlayer insulating layer 160 by the planarization process.

Since the planarization process is performed to expose the first metal layer ML1 in the first via hole VH1, a remaining portion of the first metal layer ML1 may be left in the first via hole VH1, and it may be referred to as the first via contact VC1. The uppermost surface of the first metal layer ML1 in the second via hole VH2 may be located at a height lower than the uppermost surface of the first metal layer ML1 in the first via hole VH1, and thus, after the planarization process, a remaining portion of the first metal layer ML1, a remaining portion of the second metal layer ML2, and a remaining portion of the third metal layer ML3 may be left in the second via hole VH2. The remaining portion of the first metal layer ML1, the remaining portion of the second metal layer ML2, and the remaining portion of the third metal layer ML3, which are left in the second via hole VH2, may be referred to as a first metal pattern M1, a second metal pattern M2, and a third metal pattern M3, respectively. In other words, the second via contact VC2 may include the first metal pattern M1, the second metal pattern M2, and the third metal pattern M3.

After the planarization process, a remaining portion of the second metal layer ML2 and a remaining portion of the third metal layer ML3 may be left in the first and second trenches T1 and T2, respectively. The remaining portion of the second metal layer ML2 and the remaining portion of the third metal layer ML3, which are respectively left in the first and second trenches T1 and T2, may be referred to as a first key pattern K1 and a second key pattern K2, respectively.

Upper conductive patterns 200 may be formed on the second interlayer insulating layer 160 on the first region R1. In some embodiments, the formation of the upper conductive patterns 200 may include forming an upper conductive layer on the second interlayer insulating layer 160 and patterning the upper conductive layer. Each of the first and second via contacts VC1 and VC2 may be provided to penetrate the second interlayer insulating layer 160 and may be connected to a corresponding one of the lower conductive patterns CT and a corresponding one of the upper conductive patterns 200.

A step of forming a barrier layer to fill a portion of each of the first and second via holes VH1 and VH2 before the formation of the first metal layer ML1 may be omitted to reduce electrical resistances of the first and second via contacts VC1 and VC2. The first metal layer ML1 may be formed to be thick enough to fully fill the first via hole VH1 having a relatively small width but may not fully fill the second via hole VH2 having a relatively large width. Accordingly, it may be difficult to form the second via contact VC2 having a relatively large width. In addition, since the first metal layer ML1 is formed by the selective growth process, the first metal layer ML1 may not be formed in the first and second trenches T1 and T2 exposing the inner surface of the second interlayer insulating layer 160. Thus, it may be difficult to form the first and second via contacts VC1 and VC2 and the first and second overlay key patterns KP1 and KP2 at the same time.

According to some embodiments of the inventive concepts, the first via contact VC1 may be composed of the first metal layer ML1 having a relatively low resistance, and the second via contact VC2 may include the first metal pattern M1, which includes the same material as the first via contact VC1, and the second and third metal patterns M2 and M3, which are stacked on the first metal pattern M1. Since the first via contact VC1 and the first metal pattern M1 of the second via contact VC2 are formed of the first metal layer ML1 having a relatively low resistance, the electrical resistances of the first and second via contacts VC1 and VC2 may be lowered. In addition, the second and third metal layers ML2 and ML3 may be formed to be thick enough to fully fill the second via hole VH2 having a relatively large width (i.e., the second width W2), and thus, it may be possible to easily form the second via contact VC2 having a relatively large width.

In addition, since the second and third metal layers ML2 and ML3 are formed to fill the first and second trenches T1 and T2, each of the first and second overlay key patterns KP1 and KP2 may include the first key pattern K1, which includes the same material as the second metal pattern M2 of the second via contact VC2, and the second key pattern K2, which includes the same material as the third metal pattern M3 of the second via contact VC2. In this case, the first and second overlay key patterns KP1 and KP2 and the first and second via contacts VC1 and VC2 may be formed at the same time by the planarization process.

In a semiconductor device according to example embodiments of the inventive concepts and a method of fabricating the same, it may be possible to reduce the electrical resistances of the first and second via contacts VC1 and VC2 and to form the first and second via contacts VC1 and VC2 and the first and second overlay key patterns KP1 and KP2, which have different widths from each other, at the same time.

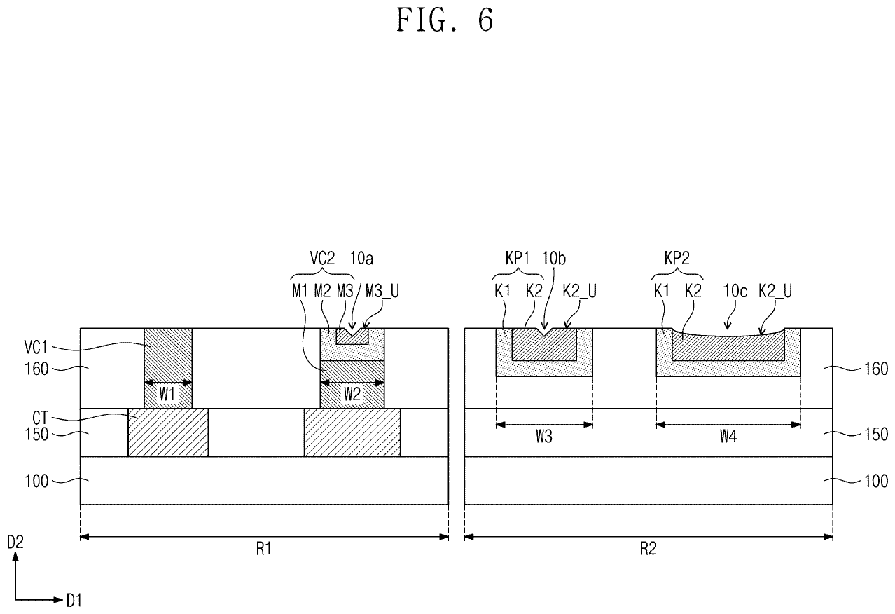

FIG. 6 is a sectional view illustrating a semiconductor device according to some embodiments of the inventive concepts. For concise description, the description that follows will mainly refer to features different from those in the semiconductor device described with reference to FIG. 1. To reduce the complexity in the drawings, the upper conductive patterns 200 of FIG. 1 are omitted from FIG. 6.

Referring to FIG. 6, the third metal pattern M3 of the second via contact VC2 may include a first recess region 10a. The first recess region 10a may be a region that is recessed from the uppermost surface M3_U of the third metal pattern M3 into the third metal pattern M3. The second key pattern K2 of the first overlay key pattern KP1 may include a second recess region 10b. The second recess region 10b may be a region that is recessed from the uppermost surface K2_U of the second key pattern K2 into the second key pattern K2. The second key pattern K2 of the second overlay key pattern KP2 may include a third recess region 10c. The third recess region 10c may be recessed into the second key pattern K2, and thus, the second key pattern K2 of the second overlay key pattern KP2 may have a recessed top surface K2_U.

The third metal pattern M3 of the second via contact VC2 and the second key pattern K2 of the first overlay key pattern KP1 may be formed using the third metal layer ML3 described with reference to FIG. 5. In this case, since the second via hole VH2 and the first trench T1 have widths smaller than the second trench T2 (i.e., W2<W4 and W3<W4), a void or seam may be formed in the third metal layer ML3 filling a remaining portion of each of the second via hole VH2 and the first trench T1. Thereafter, the planarization process described above may be performed on the third metal layer ML3, and in this case, each of the first and second recess regions 10a and 10b may be left as a portion of the void or seam, after the planarization process.

The second key pattern K2 of the second overlay key pattern KP2 may also be formed from the third metal layer ML3 of FIG. 5. The third metal layer ML3 may be formed to fill a remaining portion of the second trench T2, and then, the planarization process described above may be performed on the third metal layer ML3. In this case, since the second trench T2 has a relatively large width W4, an upper portion of the second key pattern K2 may be recessed by the planarization process to form the third recess region 10c.

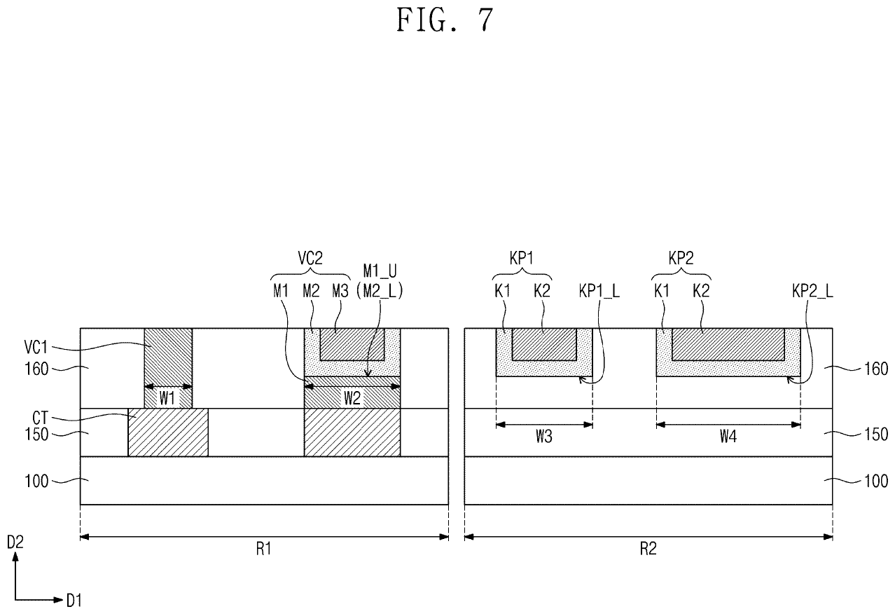

FIG. 7 is a sectional view illustrating a semiconductor device according to some embodiments of the inventive concepts. For concise description, the description that follows will mainly refer to features different from those in the semiconductor device described with reference to FIG. 1. To reduce the complexity in the drawings, the upper conductive patterns 200 of FIG. 1 are omitted from FIG. 7.

Referring to FIG. 7, the second width W2 of the second via contact VC2 may be equal to or larger than the third width W3 of the first overlay key pattern KP1. The second width W2 of the second via contact VC2 may be equal to or larger than the fourth width W4 of the second overlay key pattern KP2. In this case, the lowermost surface M2_L of the second metal pattern M2 of the second via contact VC2 may be located at a height that is equal to or lower than the lowermost surfaces KP1_L and KP2_L of the first and second overlay key patterns KP1 and KP2. Since the second width W2 of the second via contact VC2 is increased, the lowermost surface M2_L of the second metal pattern M2 of the second via contact VC2 may be placed at a lowered height.

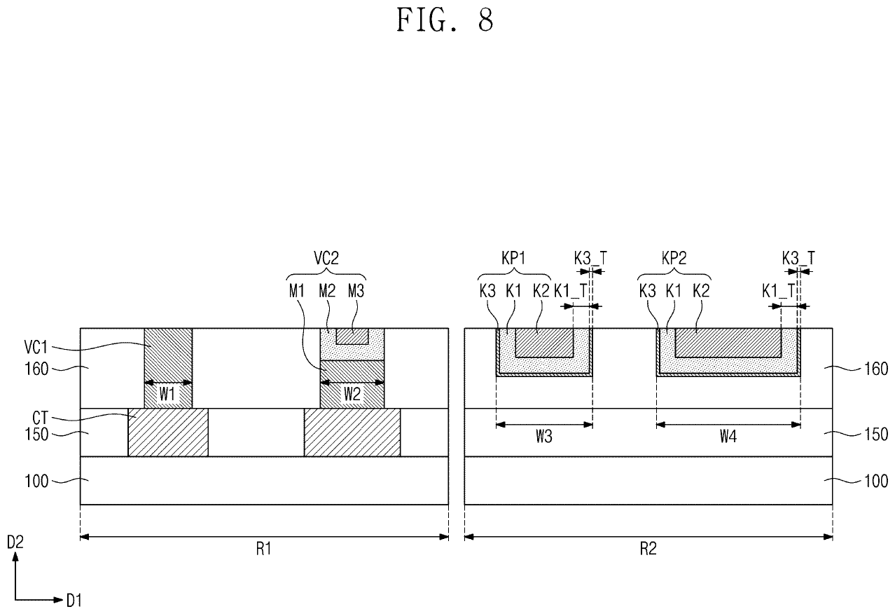

FIG. 8 is a sectional view illustrating a semiconductor device according to some embodiments of the inventive concepts. For concise description, the description that follows will mainly refer to features different from those in the semiconductor device described with reference to FIG. 1. To reduce the complexity in the drawings, the upper conductive patterns 200 of FIG. 1 are omitted from FIG. 8.

Referring to FIG. 8, each of the first and second overlay key patterns KP1 and KP2 may further include a third key pattern K3 between the first key pattern K1 and the second interlayer insulating layer 160. The third key pattern K3 may be interposed between a bottom surface of the first key pattern K1 and the second interlayer insulating layer 160 and may extend in the second direction D2 onto (e.g., to cover) side surfaces of the first key pattern K1. The third key pattern K3 may extend into a region between the side surfaces of the first key pattern K1 and the second interlayer insulating layer 160, in the second direction D2. The third key pattern K3 may have a ‘U’-shape in a sectional view.

The third key pattern K3 may include a material different from the second metal pattern M2 of the second via contact VC2 and the first key pattern K1. The third key pattern K3 may include the same material as the first via contact VC1 and the first metal pattern M1 of the second via contact VC2. As an example, the third key pattern K3 may be formed of or include molybdenum (Mo).

Each of the first and third key patterns K1 and K3 may have a thickness in a direction perpendicular to an inner surface of the second interlayer insulating layer 160 (e.g., in the first direction D1). A thickness K3_T of the third key pattern K3 may be smaller than a thickness K1_T of the first key pattern K1. In some embodiments, during the selective growth process of the first metal layer ML1 described with reference to FIG. 3, the first metal layer ML1 may be formed to conformally cover an inner surface of each of the first and second trenches T1 and T2, and in this case, the third key pattern K3 may be the first metal layer ML1 formed in each of the first and second trenches T1 and T2.

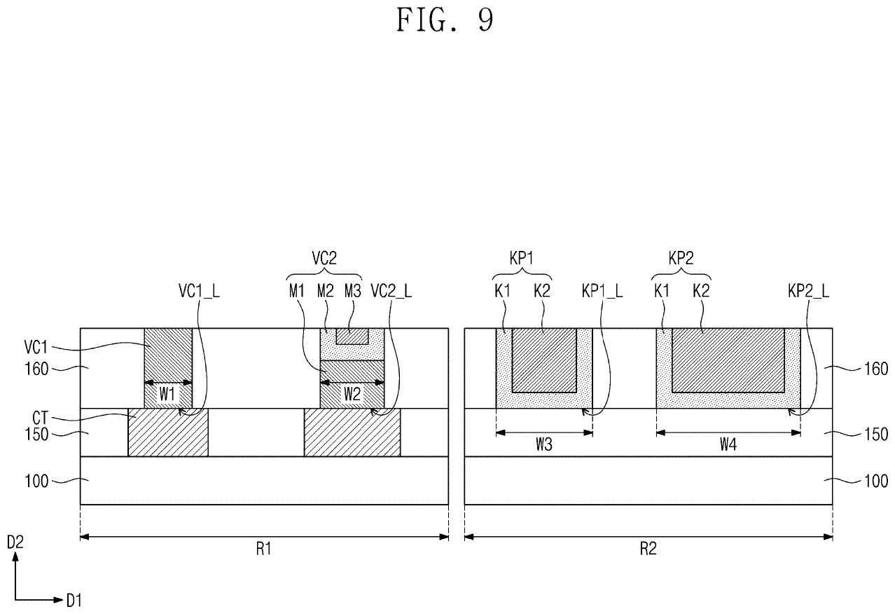

FIG. 9 is a sectional view illustrating a semiconductor device according to some embodiments of the inventive concepts. For concise description, the description that follows will mainly refer to features different from those in the semiconductor device described with reference to FIG. 1. To reduce the complexity in the drawings, the upper conductive patterns 200 of FIG. 1 are omitted from FIG. 9.

In some embodiments, as shown in FIG. 9, the lowermost surface KP1_L of the first overlay key pattern KP1 and the lowermost surface KP2_L of the second overlay key pattern KP2 may be located at a height, which is lower than or equal to the lowermost surfaces VC1_L and VC2_L of the first and second via contacts VC1 and VC2. In this case, each of the first and second overlay key patterns KP1 and KP2 may be provided to penetrate the second interlayer insulating layer 160, and the lowermost surfaces KP1_L and KP2_L of the first and second overlay key patterns KP1 and KP2 may be in contact with the first interlayer insulating layer 150.

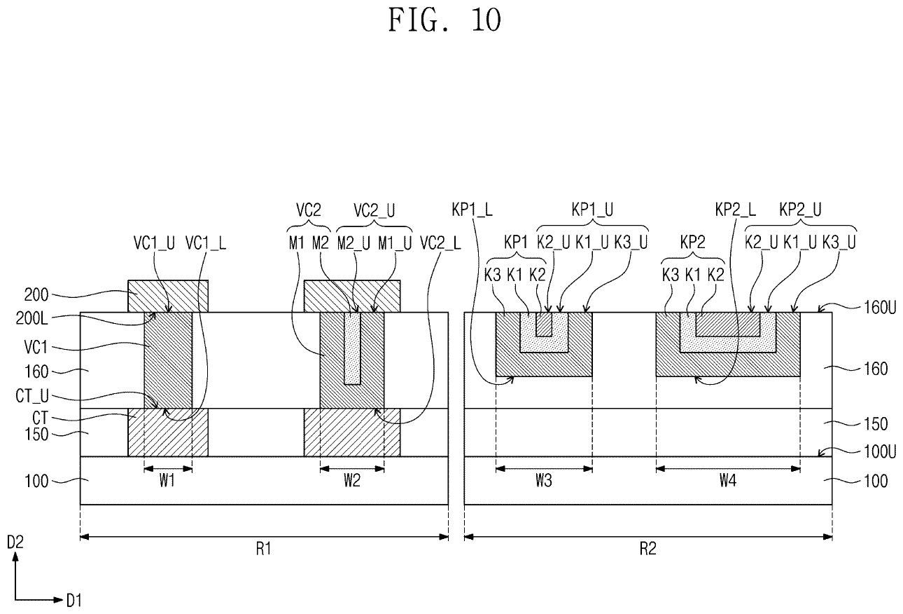

FIG. 10 is a sectional view illustrating a semiconductor device according to some embodiments of the inventive concepts. For concise description, the description that follows will mainly refer to features different from those in the semiconductor device described with reference to FIG. 1.

Referring to FIG. 10, a first via contact VC1 and a second via contact VC2 may be disposed on the lower conductive patterns CT and in the second interlayer insulating layer 160 on the first region R1. The first via contact VC1 may have a first width W1 in a direction (e.g., the first direction D1) parallel to the top surface 100U of the substrate 100, and the second via contact VC2 may have a second width W2 in the direction (e.g., the first direction D1) parallel to the top surface 100U of the substrate 100. The second width W2 may be larger than the first width W1.

The first via contact VC1 may include a metallic material, and in some embodiments, it may be formed of or include at least one of metallic materials (e.g., tungsten (W), molybdenum (Mo), ruthenium (Ru), iridium (Ir), and copper (Cu)) or alloys thereof. For example, the first via contact VC1 may be formed of or include molybdenum (Mo).

The second via contact VC2 may include a first metal pattern M1 and a second metal pattern M2 on the first metal pattern M1. The first metal pattern M1 and the second metal pattern M2 may include different materials from each other. The first metal pattern M1 may include a metallic material or a metal alloy containing at least one of tungsten (W), molybdenum (Mo), ruthenium (Ru), iridium (Ir), or copper (Cu). The second metal pattern M2 may include a metallic material, a metal alloy, a metal oxide material, a metal nitride material, or a metal oxynitride material containing at least one of tungsten (W), molybdenum (Mo), ruthenium (Ru), cobalt (Co), iridium (Ir), titanium (Ti), or tantalum (Ta). The first metal pattern M1 may include the same material as the first via contact VC1, and the second metal pattern M2 may include a material that is different from the first metal pattern M1 and the first via contact VC1. In some embodiments, the first metal pattern M1 may be formed of or include molybdenum (Mo), and the second metal pattern M2 may be formed of or include tungsten (W).

In some embodiments, the first metal pattern M1 may be interposed between a corresponding one of the lower conductive patterns CT and the second metal pattern M2 and may extend in the second direction D2 onto (e.g., to cover) side surfaces of the second metal pattern M2. The first metal pattern M1 may extend into a region between the side surfaces of the second metal pattern M2 and the second interlayer insulating layer 160, in the second direction D2. The first metal pattern M1 may have a ‘U’-shape in a sectional view.

The uppermost surface VC1_U of the first via contact VC1 and the uppermost surface VC2_U of the second via contact VC2 may not have the second interlayer insulating layer 160 thereon (e.g., may not be covered by the second interlayer insulating layer 160) and may be exposed to the outside of the second interlayer insulating layer 160. The uppermost surface VC2_U of the second via contact VC2 may include (or be defined by) the uppermost surface M1_U of the first metal pattern M1 and the uppermost surface M2_U of the second metal pattern M2. The uppermost surface VC1_U of the first via contact VC1, the uppermost surface VC2_U of the second via contact VC2, and the top surface 160U of the second interlayer insulating layer 160 may be located at the same height and may be coplanar with each other.

The lowermost surfaces VC1_L and VC2_L of the first and second via contacts VC1 and VC2 may be in contact with the top surfaces CT_U of the lower conductive patterns CT. The lowermost surface VC1_L of the first via contact VC1 may be in contact with the top surface CT_U of a corresponding one of the lower conductive patterns CT, and the lowermost surface VC2_L of the second via contact VC2 may be in contact with the top surface CT_U of a corresponding one of the lower conductive patterns CT. The lowermost surface VC2_L of the second via contact VC2 may correspond to the lowermost surface of the first metal pattern M1.

The uppermost surfaces VC1_U and VC2_U of the first and second via contacts VC1 and VC2 may be in contact with the bottom surfaces 200L of the upper conductive patterns 200. The uppermost surface VC1_U of the first via contact VC1 may be in contact with the bottom surface 200L of a corresponding one of the upper conductive patterns 200. The uppermost surface VC2_U of the second via contact VC2 may be in contact with the bottom surface 200L of a corresponding one of the upper conductive patterns 200, and the uppermost surface M1_U of the first metal pattern M1 and the uppermost surface M2_U of the second metal pattern M2 may be in contact with the bottom surface 200L of the corresponding upper conductive pattern 200.

A first overlay key pattern KP1 and a second overlay key pattern KP2 may be disposed in the second interlayer insulating layer 160 on the second region R2. The first overlay key pattern KP1 may have a third width W3 in a direction (e.g., the first direction D1) parallel to the top surface 100U of the substrate 100, and the second overlay key pattern KP2 may have a fourth width W4 in the direction (e.g., the first direction D1) parallel to the top surface 100U of the substrate 100. The fourth width W4 may be larger than the third width W3.

Each of the first and second overlay key patterns KP1 and KP2 may include a first key pattern K1, a second key pattern K2, and a third key pattern K3. The first key pattern K1 may be interposed between the second key pattern K2 and the third key pattern K3, and the third key pattern K3 may be interposed between the first key pattern K1 and the second interlayer insulating layer 160. The first key pattern K1 may be interposed between a bottom surface of the second key pattern K2 and the third key pattern K3 and may extend in the second direction D2 onto (e.g., to cover) side surfaces of the second key pattern K2. The first key pattern K1 may extend into a region between the side surfaces of the second key pattern K2 and the third key pattern K3, in the second direction D2. The first key pattern K1 may have a ‘U’-shape in a sectional view. The third key pattern K3 may be interposed between a bottom surface of the first key pattern K1 and the second interlayer insulating layer 160 and may extend in the second direction D2 onto (e.g., to cover) side surfaces of the first key pattern K1. The third key pattern K3 may extend into a region between the side surfaces of the first key pattern K1 and the second interlayer insulating layer 160, in the second direction D2. The third key pattern K3 may have a ‘U’-shape in a sectional view.

The first key pattern K1 may include a material different from the third key pattern K3. The third key pattern K3 may include the same material as the first via contact VC1 and the first metal pattern M1 of the second via contact VC2. The first key pattern K1 may include a material, which is different from the first via contact VC1 and the first metal pattern M1 of the second via contact VC2 but is the same as the second metal pattern M2 of the second via contact VC2. As an example, the third key pattern K3 may include molybdenum (Mo), and the first key pattern K1 may include tungsten (W).

The second key pattern K2 may include a metallic material, a metal alloy material, a metal oxide material, a metal nitride material, or a metal oxynitride material containing at least one of tungsten (W), molybdenum (Mo), ruthenium (Ru), iridium (Ir), copper (Cu), cobalt (Co), titanium (Ti), or tantalum (Ta). The second key pattern K2 may include the same material as the first key pattern K1 or the third key pattern K3. The second key pattern K2 may be formed of or include, for example, molybdenum (Mo) or tungsten (W).

The uppermost surface KP1_U of the first overlay key pattern KP1 and the uppermost surface KP2_U of the second overlay key pattern KP2 may not have the second interlayer insulating layer 160 thereon (e.g., may not be covered by the second interlayer insulating layer 160) and may be exposed to the outside of the second interlayer insulating layer 160. Each of the uppermost surface KP1_U of the first overlay key pattern KP1 and the uppermost surface KP2_U of the second overlay key pattern KP2 may include (or be defined by) the uppermost surface K1_U of the first key pattern K1, the uppermost surface K2_U of the second key pattern K2, and the uppermost surface K3_U of the third key pattern K3. The uppermost surface KP1_U of the first overlay key pattern KP1, the uppermost surface KP2_U of the second overlay key pattern KP2, and the top surface 160U of the second interlayer insulating layer 160 may be located at the same height and may be coplanar with each other.

In some embodiments, the lowermost surface KP1_L of the first overlay key pattern KP1 and the lowermost surface KP2_L of the second overlay key pattern KP2 may be located at a height higher than the lowermost surfaces VC1_L and VC2_L of the first and second via contacts VC1 and VC2. The lowermost surface KP1_L of the first overlay key pattern KP1 may correspond to the lowermost surface of the third key pattern K3 of the first overlay key pattern KP1, and the lowermost surface KP2_L of the second overlay key pattern KP2 may correspond to the lowermost surface of the third key pattern K3 of the second overlay key pattern KP2.

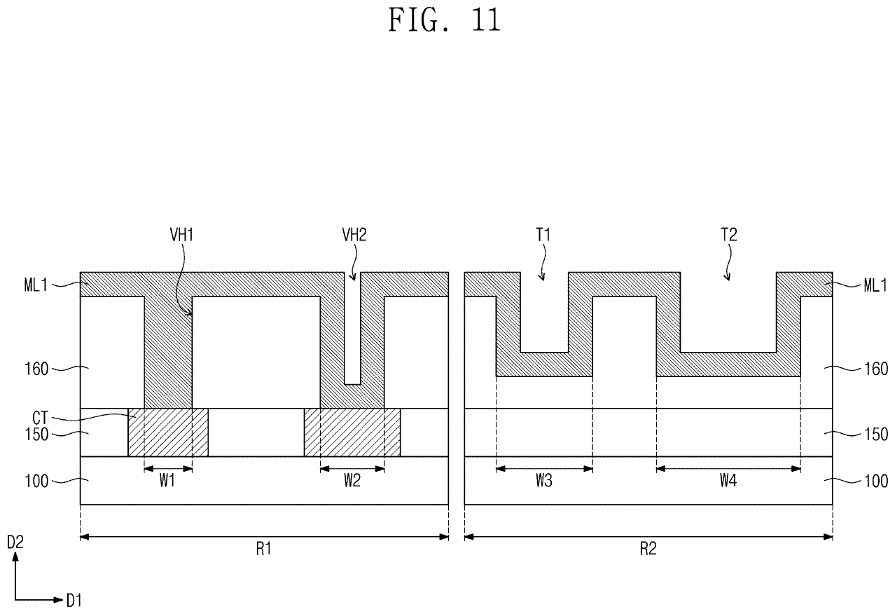

FIGS. 11 to 13 are sectional views illustrating a method of fabricating a semiconductor device, according to some embodiments of the inventive concepts. For the sake of brevity, the same technical features as those in the embodiments described with reference to FIGS. 2 to 5 may be omitted.

As described with reference to FIG. 2, a first via hole VH1 and a second via hole VH2 may be formed in the second interlayer insulating layer 160 on the first region R1, and a first trench T1 and a second trench T2 may be formed in the second interlayer insulating layer 160 on the second region R2.

Referring to FIG. 11, a first metal layer ML1 may be formed to fill the first via hole VH1, a portion of the second via hole VH2, and a portion of each of the first and second trenches T1 and T2. The first metal layer ML1 may include a metallic material with a relatively low resistance and may be formed of or include at least one of, for example, metallic materials (tungsten (W), molybdenum (Mo), ruthenium (Ru), iridium (Ir), and copper (Cu)) or alloys thereof.

In some embodiments, the first metal layer ML1 may be formed by a conformal growth process, and in this case, the first metal layer ML1 may be formed to conformally cover an inner surface of each of the first and second via holes VH1 and VH2 and the first and second trenches T1 and T2. The first metal layer ML1 may be formed to be thick enough to fully fill the first via hole VH1 having a relatively small width (the first width W1 of FIG. 2). The first metal layer ML1 may be formed to partially fill each of the second via hole VH2 and the first and second trenches T1 and T2, which have widths (e.g., the second to fourth widths W2, W3, and W4 of FIG. 2) larger than that of the first via hole VH1, and may conformally cover an inner surface of each of the second via hole VH2 and the first and second trenches T1 and T2. The first metal layer ML1 may be formed using at least one of, for example, atomic layer deposition (ALD), chemical vapor deposition (CVD), physical vapor deposition (PVD), or electroplating processes.

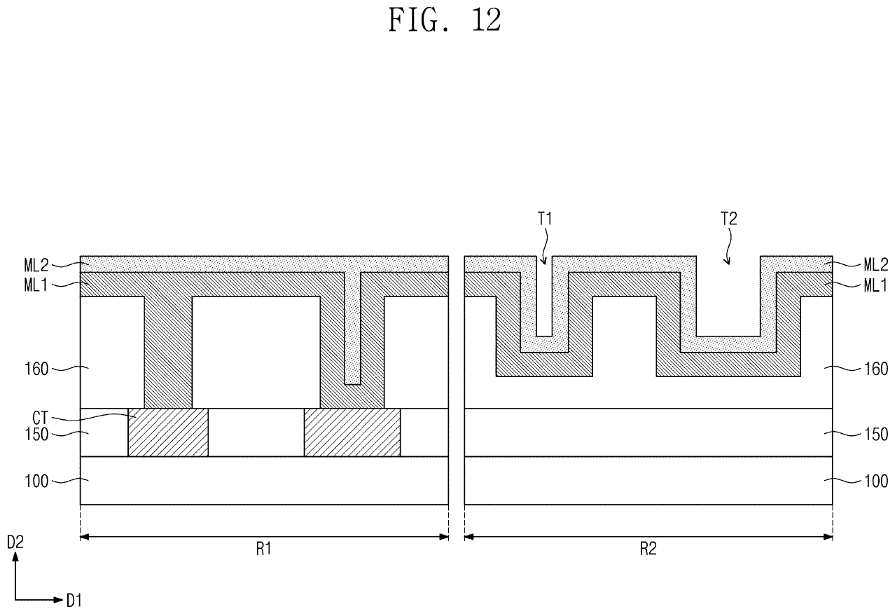

Referring to FIG. 12, a second metal layer ML2 may be formed on the first metal layer ML1 to fill a remaining portion of the second via hole VH2 and a portion of each of the first and second trenches T1 and T2. The second metal layer ML2 may be formed by a conformal growth process and may be formed to be thick enough to fully fill the remaining portion of the second via hole VH2. The second metal layer ML2 may be formed to partially fill each of the first and second trenches T1 and T2, which have widths (e.g., the third and fourth widths W3 and W4 of FIG. 2) larger than that of the second via hole VH2, and may conformally cover an inner surface of each of the first and second trenches T1 and T2. The second metal layer ML2 may be formed using at least one of, for example, atomic layer deposition (ALD), chemical vapor deposition (CVD), physical vapor deposition (PVD), or electroplating processes.

The second metal layer ML2 may include a material different from the first metal layer ML1. The second metal layer ML2 may include a metallic material, a metal alloy, a metal oxide material, a metal nitride material, or a metal oxynitride material containing at least one of tungsten (W), molybdenum (Mo), ruthenium (Ru), cobalt (Co), iridium (Ir), titanium (Ti), or tantalum (Ta).

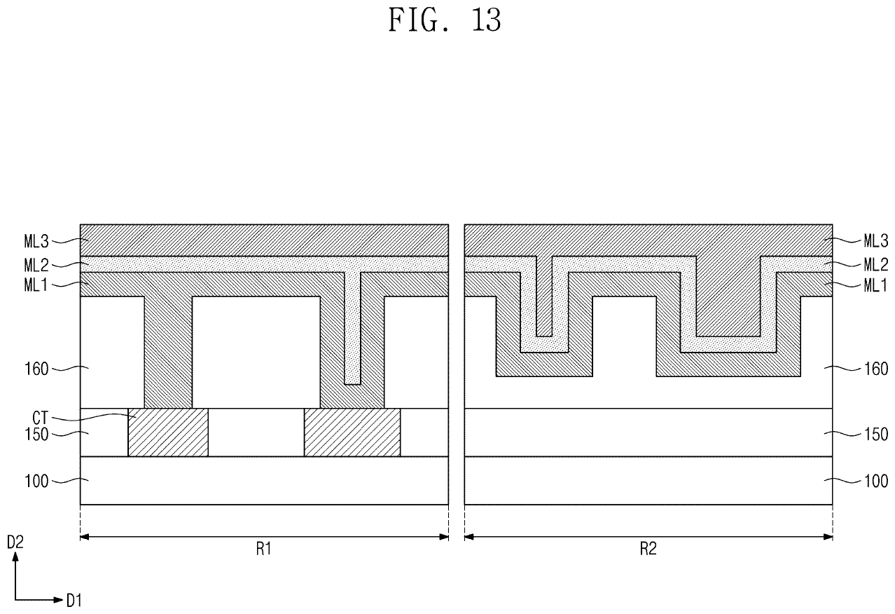

Referring to FIG. 13, a third metal layer ML3 may be formed on the second metal layer ML2 to fill a remaining portion of each of the first and second trenches T1 and T2. The third metal layer ML3 may be formed by a conformal growth process and may be formed to be thick enough to fully fill the remaining portion of each of the first and second trenches T1 and T2. In some embodiments, the third metal layer ML3 may be formed using at least one of atomic layer deposition (ALD), chemical vapor deposition (CVD), physical vapor deposition (PVD), or electroplating processes. The third metal layer ML3 may include the same material as the first metal layer ML1 or the second metal layer ML2. The third metal layer ML3 may include a metallic material, a metal alloy material, a metal oxide material, a metal nitride material, or a metal oxynitride material containing at least one of tungsten (W), molybdenum (Mo), ruthenium (Ru), iridium (Ir), copper (Cu), cobalt (Co), titanium (Ti), or tantalum (Ta).

Referring back to FIG. 10, a planarization process may be performed on the third metal layer ML3. The planarization process may be performed to expose the top surface 160U of the second interlayer insulating layer 160. As a result of the planarization process, the third metal layer ML3, the second metal layer ML2, and the first metal layer ML1 may be removed from a top surface of the second interlayer insulating layer 160. As a result of the planarization process, a first via contact VC1, a second via contact VC2, a first overlay key pattern KP1, and a second overlay key pattern KP2 may be formed in the second interlayer insulating layer 160.

A remaining portion of the first metal layer ML1, which is left in the first via hole VH1 after the planarization process, may be referred to as the first via contact VC1. A remaining portion of the first metal layer ML1 and a remaining portion of the second metal layer ML2, which are left in the second via hole VH2 after the planarization process, may be referred to as a first metal pattern M1 and a second metal pattern M2, respectively. A remaining portion of the first metal layer ML1, which is left in each of the first and second trenches T1 and T2 after the planarization process, may be referred to as a third key pattern K3, and a remaining portion of the second metal layer ML2, which is left in each of the first and second trenches T1 and T2 after the planarization process, may be referred to as a first key pattern K1. A remaining portion of the third metal layer ML3, which is left in each of the first and second trenches T1 and T2 after the planarization process, may be referred to as a second key pattern K2.

According to example embodiments of the inventive concepts, since the first via contact VC1 and the first metal pattern M1 of the second via contact VC2 are formed of the first metal layer ML1 having a relatively low resistance, the electrical resistances of the first and second via contacts VC1 and VC2 may be lowered. In addition, the second metal layer ML2 may be formed to fill a remaining portion of the second via hole VH2 having a relatively large width (i.e., the second width W2), and in this case, it may be possible to easily form the second via contact VC2 having a relatively large width. In addition, the second and third metal layers ML2 and ML3 may be formed to fill a remaining portion of each of the first and second trenches T1 and T2, and in this case, the first and second overlay key patterns KP1 and KP2 and the first and second via contacts VC1 and VC2 may be formed at the same time by the planarization process.

In a semiconductor device according to example embodiments of the inventive concepts and a method of fabricating the same, it may be possible to reduce the electrical resistances of the first and second via contacts VC1 and VC2 and to form the first and second via contacts VC1 and VC2 and the first and second overlay key patterns KP1 and KP2, which have different widths from each other, at the same time.

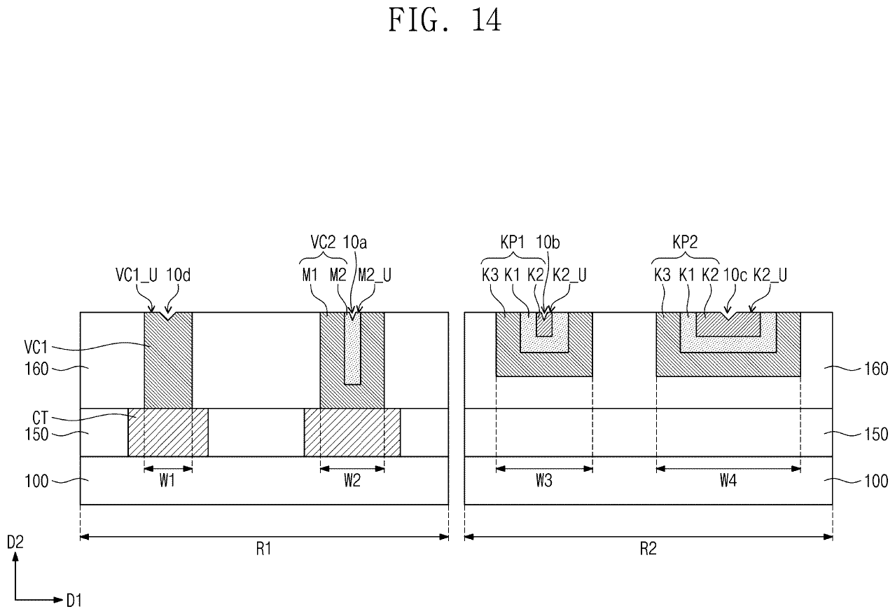

FIG. 14 is a sectional view illustrating a semiconductor device according to some embodiments of the inventive concepts. For concise description, the description that follows will mainly refer to features different from those in the semiconductor device described with reference to FIG. 10. To reduce the complexity in the drawings, the upper conductive patterns 200 of FIG. 10 are omitted from FIG. 14.

Referring to FIG. 14, the second metal pattern M2 of the second via contact VC2 may include a first recess region 10a. The first recess region 10a may be a region, which is recessed from the uppermost surface M2_U of the second metal pattern M2 into the second metal pattern M2. The second key pattern K2 of the first overlay key pattern KP1 may include a second recess region 10b. The second recess region 10b may be a region, which is recessed from the uppermost surface K2_U of the second key pattern K2 into the second key pattern K2. The second key pattern K2 of the second overlay key pattern KP2 may include a third recess region 10c. The third recess region 10c may be a region, which is recessed from the uppermost surface K2_U of the second key pattern K2 into the second key pattern K2. In some embodiments, the first via contact VC1 may include a fourth recess region 10d. The fourth recess region 10d may be a region, which is recessed from the uppermost surface VC1_U of the first via contact VC1 into the first via contact VC1.

Since the first to third metal layers ML1, ML2, and ML3 described with reference to FIGS. 11 to 13 are formed by the conformal growth process, a void or seam may be formed in the first to third metal layers ML1, ML2, and ML3, and the afore-described planarization process may be performed. The first to fourth recess regions 10a, 10b, 10c, and 10d may be a portion of the void or seam, which is left after the planarization process.

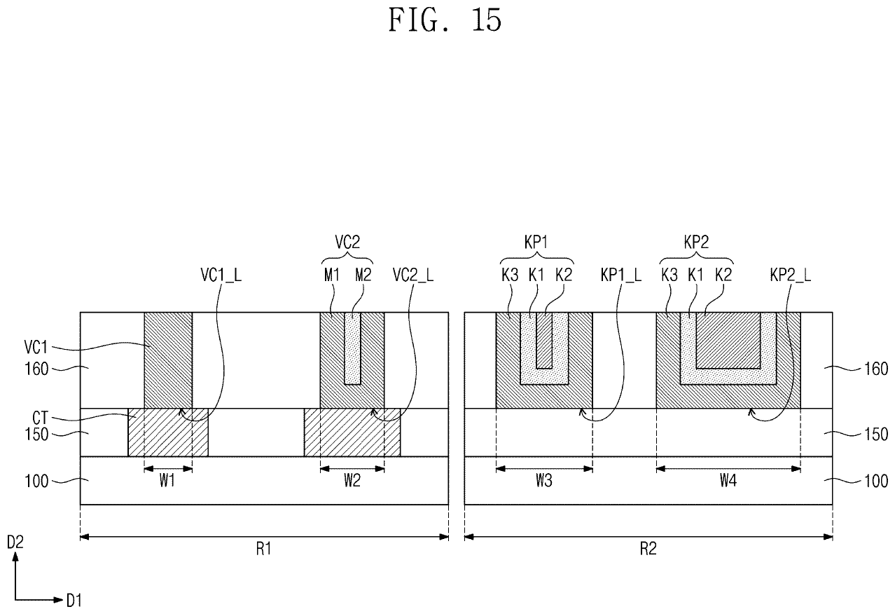

FIG. 15 is a sectional view illustrating a semiconductor device according to some embodiments of the inventive concepts. For concise description, the description that follows will mainly refer to features different from those in the semiconductor device described with reference to FIG. 10. To reduce the complexity in the drawings, the upper conductive patterns 200 of FIG. 10 are omitted from FIG. 15.

In some embodiments, as shown in FIG. 15, the lowermost surface KP1_L of the first overlay key pattern KP1 and the lowermost surface KP2_L of the second overlay key pattern KP2 may be located at a height, which is lower than or equal to the lowermost surfaces VC1_L and VC2_L of the first and second via contacts VC1 and VC2. In this case, each of the first and second overlay key patterns KP1 and KP2 may be provided to penetrate the second interlayer insulating layer 160, and the lowermost surfaces KP1_L and KP2_L of the first and second overlay key patterns KP1 and KP2 may be in contact with the first interlayer insulating layer 150.

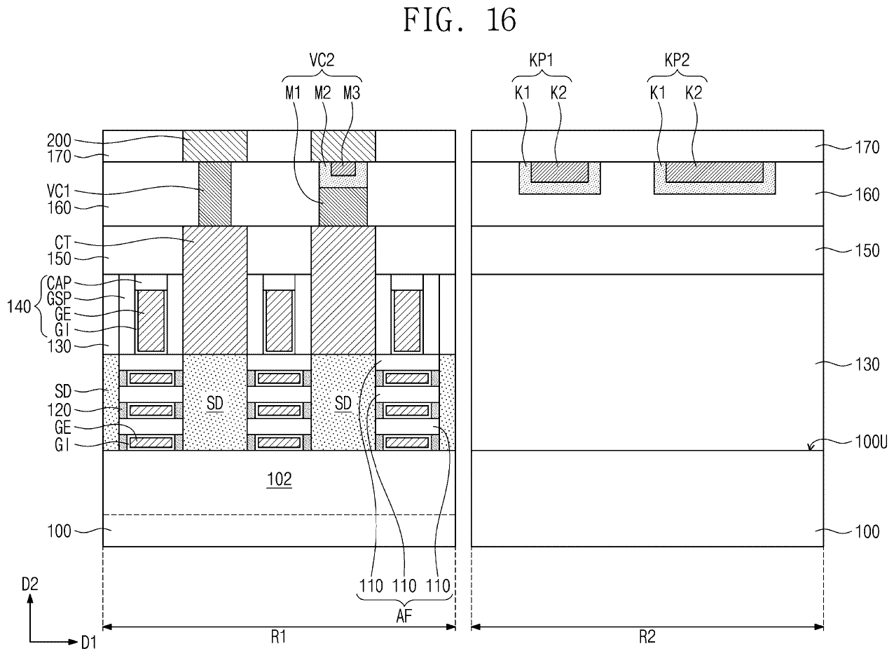

FIG. 16 is a sectional view illustrating a semiconductor device according to some embodiments of the inventive concepts. For concise description, an element previously described with reference to FIGS. 1 to 15 may be identified by the same reference number without repeating an overlapping description thereof.

Referring to FIG. 16, a substrate 100 including at least two different regions (e.g., a first region R1 and a second region R2) may be provided. The first region R1 may be a cell region, on which memory cells of the semiconductor device are disposed, and the second region R2 may be a key region provided with overlay key patterns, which are used for alignment of a photomask during a photolithography process. The substrate 100 may be a semiconductor substrate. For example, the substrate 100 may be a silicon substrate, a germanium substrate, a silicon-germanium substrate, or a silicon-on-insulator (SOI) substrate.

The substrate 100 may include an active region 102, which is provided on the first region R1. The active region 102 may extend in a first direction D1 parallel to the top surface 100U of the substrate 100 and may protrude from a lower portion of the substrate 100 in an upward direction (e.g., in a second direction D2 perpendicular to the top surface 100U of the substrate 100). Although not shown, device isolation patterns may be disposed on the substrate 100 to define the active region 102.

An active fin AF and source/drain patterns SD may be disposed on the active region 102. The source/drain patterns SD (which may also be referred to as source/drain terminals) may be spaced apart from each other in the first direction D1 with the active fin AF interposed therebetween. In some embodiments, the active fin AF may include a plurality of semiconductor patterns 110, which are spaced apart from each other in the second direction D2. The lowermost one of the semiconductor patterns 110 may be spaced apart from the active region 102 in the second direction D2. The semiconductor patterns 110 may be interposed between the source/drain patterns SD and may be connected to the source/drain patterns SD. Each of the source/drain patterns SD may be in contact with side surfaces of the semiconductor patterns 110. Each of the semiconductor patterns 110 may connect the source/drain patterns SD to each other. FIG. 16 illustrates an example, in which the active fin AF includes three semiconductor patterns 110, but the inventive concepts are not limited to this example. The semiconductor patterns 110 may be formed of or include at least one of silicon (Si), silicon germanium (SiGe), or germanium (Ge).

The source/drain patterns SD may be epitaxial patterns, which are formed using the semiconductor patterns 110 and the active region 102 as a seed layer. The source/drain patterns SD may be formed of or include at least one of silicon germanium (SiGe), silicon (Si), or silicon carbide (SiC). In some embodiments, the source/drain patterns SD may be configured to exert a tensile strain on the active fin AF. In the case where the semiconductor patterns 110 include silicon (Si), the source/drain patterns SD may be formed of or include silicon (Si) and/or silicon carbide (SiC). In other embodiments, the source/drain patterns SD may be configured to exert a compressive strain on the active fin AF. In the case where the semiconductor patterns 110 include silicon (Si), the source/drain patterns SD may be formed of or include silicon germanium (SiGe). The source/drain patterns SD may further include an impurity. The impurity may be used to improve the electrical characteristics of a transistor including the source/drain patterns SD. In the case where the transistor is an NMOSFET, the impurity may be, for example, phosphorus (P). In the case where the transistor is a PMOSFET, the impurity may be, for example, boron (B).

A gate structure 140 may be provided on the active fin AF to cross the active fin AF. The active fin AF may be vertically overlapped with the gate structure 140, and the source/drain patterns SD may be respectively formed at opposing sides of the gate structure 140. As used herein, “an element A overlaps an element B in a direction X” (or similar language) means that there is at least one straight line that extends in the direction X and intersects both the elements A and B.

The gate structure 140 (which may also be referred to as a gate terminal) may include a gate electrode GE, a gate insulating pattern GI between the gate electrode GE and the active fin AF, gate spacers GSP on side surfaces of the gate electrode GE, and a gate capping pattern CAP on a top surface of the gate electrode GE. The gate insulating pattern GI may extend into regions between the gate electrode GE and the gate spacers GSP, and the uppermost surface of the gate insulating pattern GI may be substantially coplanar with the top surface of the gate electrode GE. The gate electrode GE may be on (e.g., may cover) the uppermost surface of the active fin AF and may fill spaces between the active fin AF and the active region 102 and between the semiconductor patterns 110. The gate insulating pattern GI may be interposed between each of the semiconductor patterns 110 and the gate electrode GE. Each of the semiconductor patterns 110 may be spaced apart from the gate electrode GE with the gate insulating pattern GI interposed therebetween. The gate electrode GE, the active fin AF, and the source/drain patterns SD may constitute a multi-bridge channel field effect transistor (MBCFET).

The gate electrode GE may be formed of or include at least one of doped semiconductor materials, conductive metal nitride materials, and/or metallic materials. The gate insulating pattern GI may be formed of or include at least one of silicon oxide, silicon nitride, silicon oxynitride, or high-k dielectric materials. The high-k dielectric materials may include materials (e.g., hafnium oxide (HfO), aluminum oxide (AlO), or tantalum oxide (TaO)) having higher dielectric constants than silicon oxide. Each of the gate spacers GSP and the gate capping pattern CAP may include at least one of a silicon oxide layer, a silicon nitride layer, or a silicon oxynitride layer.

Spacer patterns 120 may be provided between each of the source/drain patterns SD and the gate electrode GE. The spacer patterns 120 may be provided to enclose the gate electrode GE and may be spaced apart from each other in the second direction D2. The spacer patterns 120 and the semiconductor patterns 110 may be alternately and repeatedly stacked in the second direction D2. Each of the spacer patterns 120 may be disposed between adjacent ones of the semiconductor patterns 110 or between the lowermost one of the semiconductor patterns 110 and the active region 102. Each of the source/drain patterns SD may be in contact with the semiconductor patterns 110 and may be spaced apart from the gate electrode GE, with the spacer patterns 120 interposed therebetween. The gate insulating pattern GI may be interposed between the gate electrode GE and each of the semiconductor patterns 110 and may extend into a region between the gate electrode GE and each of the spacer patterns 120. Each of the spacer patterns 120 may be in contact with the gate insulating pattern GI. In some embodiments, the spacer patterns 120 may include at least one of a silicon oxide layer, a silicon nitride layer, a silicon oxynitride layer, or low-k dielectric layers.

A lower interlayer insulating layer 130 may be provided on the first region R1 of the substrate 100 and may be on (e.g., may cover) the gate structure 140 and the source/drain patterns SD. The lower interlayer insulating layer 130 may extend to the second region R2 of the substrate 100 to be on (e.g., to cover) the top surface 100U of the substrate 100. The lower interlayer insulating layer 130 may include at least one of a silicon oxide layer, a silicon nitride layer, a silicon oxynitride layer, or low-k dielectric layers. A top surface of the gate capping pattern CAP may be substantially coplanar with a top surface of the lower interlayer insulating layer 130. The gate spacer GSP may be interposed between the gate capping pattern CAP and the lower interlayer insulating layer 130.

A first interlayer insulating layer 150 may be disposed on the lower interlayer insulating layer 130 on the first region R1 to be on (e.g., to cover) the top surface of the gate capping pattern CAP. The first interlayer insulating layer 150 may extend to be on (e.g., to cover) the lower interlayer insulating layer 130 on the second region R2. The first interlayer insulating layer 150 may include at least one of a silicon oxide layer, a silicon nitride layer, a silicon oxynitride layer, or low-k dielectric layers.

Lower conductive patterns CT may be formed in the first interlayer insulating layer 150 on the first region R1. Each of the lower conductive patterns CT may penetrate the first interlayer insulating layer 150 and the lower interlayer insulating layer 130 and may be electrically connected to a corresponding one of the source/drain patterns SD. The lower conductive patterns CT may be disposed at opposing sides of the gate structure 140 and may be electrically connected to the source/drain patterns SD. The lower conductive patterns CT may include a conductive material (e.g., metal).

A second interlayer insulating layer 160 may be disposed on the first interlayer insulating layer 150 and may be on (e.g., may cover) top surfaces of the lower conductive patterns CT. The second interlayer insulating layer 160 may be disposed on the first interlayer insulating layer 150 in the first region R1 and may extend to a region on the first interlayer insulating layer 150 in the second region R2. The second interlayer insulating layer 160 may include at least one of a silicon oxide layer, a silicon nitride layer, a silicon oxynitride layer, or low-k dielectric layers.

A first via contact VC1 and a second via contact VC2 may be disposed on the lower conductive patterns CT and in the second interlayer insulating layer 160 on the first region R1. Each of the first and second via contacts VC1 and VC2 may be provided to penetrate the second interlayer insulating layer 160 and may be electrically connected to a corresponding one of the lower conductive patterns CT. The first and second via contacts VC1 and VC2 may have substantially the same features as the first and second via contacts VC1 and VC2 described with reference to FIGS. 1 to 15.

A first overlay key pattern KP1 and a second overlay key pattern KP2 may be disposed in the second interlayer insulating layer 160 on the second region R2. The first and second overlay key patterns KP1 and KP2 may be horizontally spaced apart from the first and second via contacts VC1 and VC2 (e.g., in the first direction D1). Each of the first and second overlay key patterns KP1 and KP2 may be provided to penetrate at least a portion of the second interlayer insulating layer 160. The first and second overlay key patterns KP1 and KP2 may have substantially the same features as the first and second overlay key patterns KP1 and KP2 described with reference to FIGS. 1 to 15.

Upper conductive patterns 200 may be disposed on the second interlayer insulating layer 160 in the first region R1 and may be electrically connected to the first and second via contacts VC1 and VC2. Each of the first and second via contacts VC1 and VC2 may be provided to penetrate the second interlayer insulating layer 160 and may be connected to a corresponding one of the lower conductive patterns CT and a corresponding one of the upper conductive patterns 200. The upper conductive patterns 200 may have substantially the same features as the upper conductive patterns 200 described with reference to FIGS. 1 to 15.

A third interlayer insulating layer 170 may be disposed on the second interlayer insulating layer 160 in the first region R1 to be on (e.g., to cover) the upper conductive patterns 200. The third interlayer insulating layer 170 may extend to a region on the second interlayer insulating layer 160 in the second region R2 to be on (e.g., to cover) the uppermost surfaces of the first and second overlay key patterns KP1 and KP2. The third interlayer insulating layer 170 may include at least one of a silicon oxide layer, a silicon nitride layer, a silicon oxynitride layer, or low-k dielectric layers.

According to example embodiments of the inventive concepts, since the first via contact VC1 and the first metal pattern M1 of the second via contact VC2 include a metal material having a relatively low resistance, electrical resistances of the first and second via contacts VC1 and VC2 may be lowered. In addition, the first and second via contacts VC1 and VC2 and the first and second overlay key patterns KP1 and KP2, which have different widths from each other, may be formed at the same time. Thus, in a semiconductor device according to example embodiments of the inventive concepts and a method of fabricating the same, it may be possible to reduce the electrical resistances of the first and second via contacts VC1 and VC2 and to form the first and second via contacts VC1 and VC2 and the first and second overlay key patterns KP1 and KP2, which have different widths from each other, with ease.

In a semiconductor device according to example embodiments of the inventive concepts and a method of fabricating the same, it may be possible to reduce electrical resistances of via contacts and to easily form the via contacts and overlay key patterns, which have different widths from each other.

While example embodiments of the inventive concepts have been particularly shown and described, it will be understood by one of ordinary skill in the art that variations in form and detail may be made therein without departing from the scope of the attached claims.

What is claimed is:

1. A semiconductor device, comprising:
lower conductive patterns on a substrate and horizontally spaced apart from each other;
upper conductive patterns on the lower conductive patterns and horizontally spaced apart from each other; and
a first via contact and a second via contact between the lower conductive patterns and the upper conductive patterns and horizontally spaced apart from each other,
wherein the first via contact has a first width in a first direction parallel to a top surface of the substrate,
wherein the second via contact has a second width in the first direction that is wider than the first width,
wherein the second via contact comprises a first metal pattern and a second metal pattern on the first metal pattern,
wherein the first metal pattern comprises a same material as the first via contact, and
wherein the second metal pattern comprises a different material from the first metal pattern and the first via contact.

2. The semiconductor device of claim 1, wherein a lowermost surface of the first via contact is in contact with a top surface of a first lower conductive pattern among the lower conductive patterns, and a lowermost surface of the second via contact is in contact with a top surface of a second lower conductive pattern among the lower conductive patterns, and
wherein an uppermost surface of the first via contact is in contact with a bottom surface of a first upper conductive pattern among the upper conductive patterns, and an uppermost surface of the second via contact is in contact with a bottom surface of a second upper conductive pattern among the upper conductive patterns.

3. The semiconductor device of claim 2, wherein an uppermost surface of the second metal pattern is in contact with the bottom surface of the second upper conductive pattern.

4. The semiconductor device of claim 3, wherein an uppermost surface of the first metal pattern is located at a height from the top surface of the substrate that is lower than a height of the uppermost surface of the first via contact from the top surface of the substrate.

5. The semiconductor device of claim 4, wherein the second via contact further comprises a third metal pattern on the second metal pattern,
wherein a first portion of the second metal pattern is between the first metal pattern and the third metal pattern, and a second portion of the second metal pattern is on a side surface of the third metal pattern, and
wherein an uppermost surface of the third metal pattern is in contact with the bottom surface of the second upper conductive pattern.

6. The semiconductor device of claim 3, wherein a first portion of the first metal pattern is between the second lower conductive pattern and the second metal pattern, and a second portion of the first metal pattern is on a side surface of the second metal pattern.

7. The semiconductor device of claim 6, wherein an uppermost surface of the first metal pattern is in contact with the bottom surface of the second upper conductive pattern.

8. The semiconductor device of claim 1, further comprising:
a first interlayer insulating layer on the substrate and on side surfaces of the lower conductive patterns; and
a second interlayer insulating layer on the first interlayer insulating layer and on side surfaces of the first and second via contacts,
wherein the upper conductive patterns are on the second interlayer insulating layer,
wherein the first via contact extends into the second interlayer insulating layer and is electrically connected to a first lower conductive pattern among the lower conductive patterns and a first upper conductive pattern among the upper conductive patterns, and
wherein the second via contact extends into the second interlayer insulating layer and is electrically connected to a second lower conductive pattern among the lower conductive patterns and a second upper conductive pattern among the upper conductive patterns.

9. The semiconductor device of claim 8, wherein the second via contact further comprises a third metal pattern on the second metal pattern,
wherein the first metal pattern is between the second lower conductive pattern and the second metal pattern, and
wherein a first portion of the second metal pattern is between the first metal pattern and the third metal pattern, and a second portion of the second metal pattern is between the third metal pattern and the second interlayer insulating layer.

10. The semiconductor device of claim 8, wherein a first portion of the first metal pattern is between the second lower conductive pattern and the second metal pattern, and a second portion of the first metal pattern is between the second metal pattern and the second interlayer insulating layer.

11. The semiconductor device of claim 8, further comprising an overlay key pattern in the second interlayer insulating layer and horizontally spaced apart from the first and second via contacts,
wherein the overlay key pattern comprises a first key pattern and a second key pattern on the first key pattern,
wherein a first portion of the first key pattern is between a bottom surface of the second key pattern and the second interlayer insulating layer, and a second portion of the first key pattern is between a side surface of the second key pattern and the second interlayer insulating layer, and
wherein the first key pattern comprises a same material as the second metal pattern.

12. The semiconductor device of claim 11, wherein the overlay key pattern further comprises a third key pattern between the first key pattern and the second interlayer insulating layer, and
wherein the third key pattern comprises a same material as the first metal pattern.

13. The semiconductor device of claim 12, wherein a first portion of the third key pattern is between a bottom surface of the first key pattern and the second interlayer insulating layer, and a second portion of the third key pattern is between a side surface of the first key pattern and the second interlayer insulating layer.

14. A semiconductor device, comprising:
transistors on a substrate;
lower conductive patterns electrically connected to gate terminals or source/drain terminals of the transistors and horizontally spaced apart from each other;
upper conductive patterns on the lower conductive patterns and horizontally spaced apart from each other; and
a first via contact and a second via contact between the lower conductive patterns and the upper conductive patterns and horizontally spaced apart from each other,
wherein the first via contact electrically connects a first lower conductive pattern among the lower conductive patterns to a first upper conductive pattern among the upper conductive patterns, and the second via contact electrically connects a second lower conductive pattern among the lower conductive patterns to a second upper conductive pattern among the upper conductive patterns,
wherein the first via contact has a first width in a first direction parallel to a top surface of the substrate,
wherein the second via contact has a second width in the first direction that is wider than the first width,
wherein the second via contact comprises a first metal pattern and a second metal pattern on the first metal pattern,
wherein the first metal pattern comprises a same material as the first via contact, and
wherein the second metal pattern comprises a different material from the first metal pattern and the first via contact.

15. The semiconductor device of claim 14, further comprising an interlayer insulating layer between the lower conductive patterns and the upper conductive patterns,
wherein the first via contact extends into the interlayer insulating layer and electrically connects the first lower conductive pattern to the first upper conductive pattern, and
wherein the second via contact extends into the interlayer insulating layer and electrically connects the second lower conductive pattern to the second upper conductive pattern.

16. The semiconductor device of claim 15, further comprising an overlay key pattern horizontally spaced apart from the first and second via contacts,
wherein the substrate comprises a first region and a second region different from the first region,
wherein the transistors, the lower conductive patterns, the upper conductive patterns, the first and second via contacts, and the interlayer insulating layer are on the first region of the substrate,
wherein the interlayer insulating layer extends onto the second region of the substrate,
wherein the overlay key pattern is in the interlayer insulating layer on the second region,
wherein the overlay key pattern comprises a first key pattern and a second key pattern on the first key pattern, and
wherein the first key pattern comprises a same material as the second metal pattern.

17. The semiconductor device of claim 16, wherein a first portion of the first key pattern is between a bottom surface of the second key pattern and the interlayer insulating layer, and a second portion of the first key pattern is between a side surface of the second key pattern and the interlayer insulating layer.

18. The semiconductor device of claim 17, wherein the second via contact further comprises a third metal pattern on the second metal pattern, and
wherein the second key pattern comprises a same material as the third metal pattern.

19. The semiconductor device of claim 17, wherein the overlay key pattern further comprises a third key pattern between the first key pattern and the interlayer insulating layer, and
wherein the third key pattern comprises a same material as the first metal pattern.

20. A semiconductor device, comprising:
a first lower conductive pattern on a substrate;
a second lower conductive pattern on the substrate and horizontally spaced apart from the first lower conductive pattern;
a first upper conductive pattern on the first lower conductive pattern;
a second upper conductive pattern on the second lower conductive pattern and horizontally spaced apart from the first upper conductive pattern;
a first via contact electrically connected between the first lower conductive pattern and the first upper conductive pattern; and
a second via contact electrically connected between the second lower conductive pattern and the second upper conductive pattern,
wherein the first via contact has a first width in a direction parallel to a top surface of the substrate,
wherein the second via contact has a second width in the direction that is different from the first width,
wherein the second via contact comprises a first metal pattern and a second metal pattern on the first metal pattern, and
wherein one of the first and second metal patterns comprises a same material as the first via contact, and another one of the first and second metal patterns comprises a different material from the first via contact.
